(19) United States
(12) Patent Application Publication
(10) Pub. No.: US 2009/0004868 A1
(43) Pub. Date: Jan. 1, 2009

(54) Amorphous silicon oxidation patterning

(76) Inventors: Brian S. Doyle, Portland, OR (US); Uday Shah, Portland, OR (US); Jack T. Kavalieros, Portland, OR (US)

Correspondence Address: CAVEN & AGHEVLI;c/o INTELLEVATE, LLC, P.O. BOX 52050, MINNEAPOLIS, MN, 55402, US

(21) Appl. No.: 11/824,489

(22) Filed: Jun. 29, 2007

(51) Int. Cl. H01L 21/311

(52) U.S. Cl. 438/702; 257/E21.249

(57) ABSTRACT

In one embodiment, a method comprises forming a sacrificial amorphous silicon layer on a semiconductor substrate, forming a hardmask on the amorphous silicon layer, etching one or more lines in the sacrificial amorphous silicon layer, growing oxide structures on the amorphous silicon layer, and forming a trench in the semiconductor substrate between the oxide structures.

### BACKGROUND

The subject matter described herein relates generally to the semiconductor integrated circuit manufacturing.

Today's computer chips are increasingly dependent on robust memory architecture capable of quickly accessing and handling large amounts of data. Existing memory solutions such as off-chip physical dynamic random access memory (DRAM) that sit on the mother board separate from the computer chip require relatively large amounts of energy and suffer from high latency, resulting in power-performance loss. Latency problems have been addressed using 1T-1C DRAM cells embedded on the computer chip, but existing versions of such DRAM cells are frequently unable to meet ever-increasing capacitance demands. Accordingly, there exists a need for a manufacturing techniques to produce large-size, high-density capacitors compatible with a 1T-1C embedded DRAM cell usable within a logic technology process.

### BRIEF DESCRIPTION OF THE DRAWINGS

The detailed description is described with reference to the accompanying figures.

FIG. 1 is a flowchart illustrating operations in a method of amorphous silicon oxidation patterning, in accordance with some embodiments.

FIGS. 2A-2K are schematic illustrations of a semiconductor material during processing, in accordance with some embodiments.

FIG. 3 is a schematic illustration of a computing system which may incorporate a thermal interface in accordance with some embodiments.

For simplicity and clarity of illustration, the drawing Figures illustrate the general manner of construction, and descriptions and details of well-known features and techniques may be omitted to avoid unnecessarily obscuring the discussion of the described embodiments of the invention. Additionally, elements in the drawing Figures are not necessarily drawn to scale. For example, the dimensions of some of the elements in the Figures may be exaggerated relative to other elements to help improve understanding of embodiments of the present invention. The same reference numerals in different Figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used.

### DETAILED DESCRIPTION

In some embodiments, techniques described herein may be used to produce silicon substrates having fin structures commonly used to form metal-insulator-metal (MIM) capacitors used as a basic building block of transistors used in memory circuits such as, e.g., dynamic random access memory (DRAM) circuits. As described herein, a amorphous silicon layer defines gaps between fin structures on the underlying silicon substrate. In some embodiments the amorphous silicon lay is patterned and allowed to oxidize in a controlled oxidation growth process. The regions of oxide growth define the fin structures on the underlying silicon substrate.

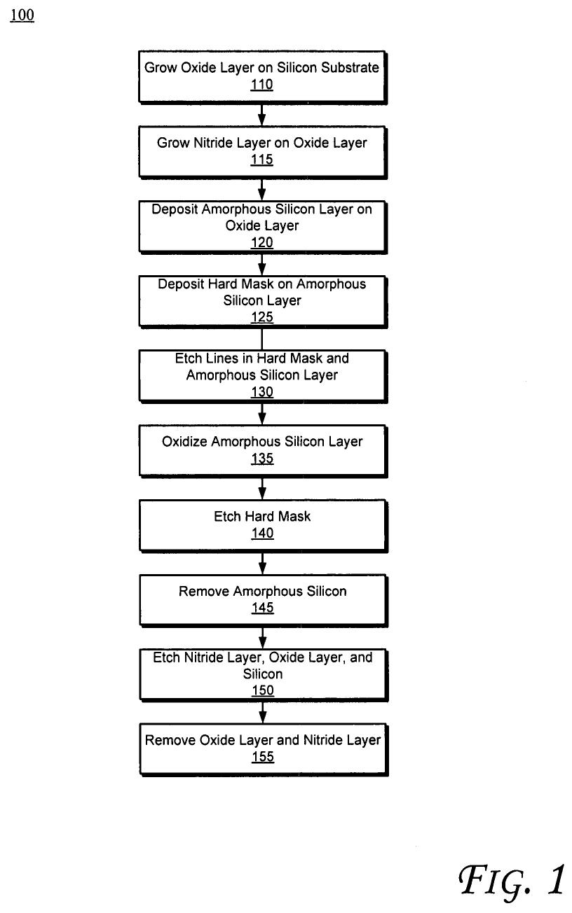

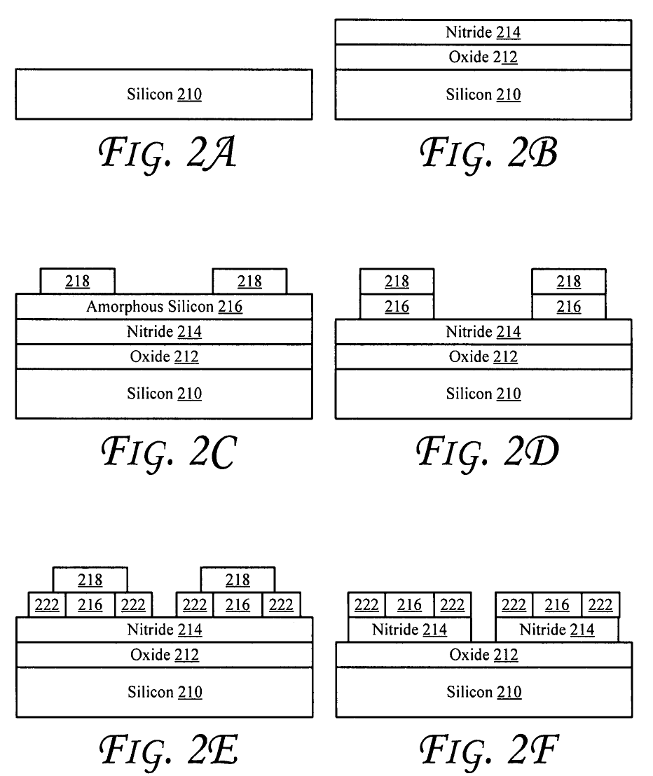

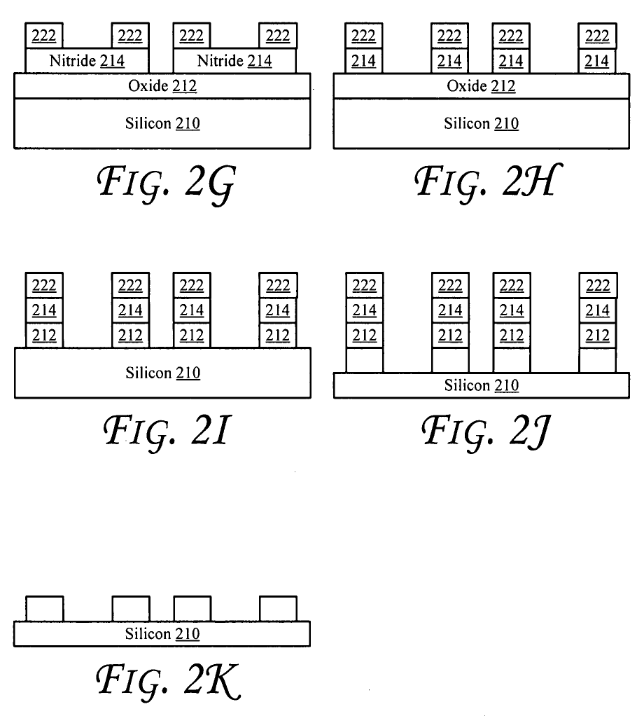

FIG. 1 is a flowchart illustrating operations in a method of amorphous silicon oxidation patterning, in accordance with some embodiments, and FIGS. 2A-2K are schematic illustrations of a semiconductor material during processing, in accordance with some embodiments. In some embodiments, the operations of FIG. 1 may be performed on a suitable substrate such as a silicon substrate 210 depicted in FIG. 2A. In some embodiments, substrate 210 is comprised of a silicon semiconductor substrate having a doped epitaxial silicon region with either p-type or n-type conductivity. In some embodiment of the present invention, the substrate 210 is comprised of a silicon semiconductor substrate having an undoped, or intrinsic epitaxial silicon region.

Referring to FIG. 1, at operation 110 an oxide layer is formed on the substrate, and at operation 115 a nitride layer is formed on the oxide layer. In some embodiments, the oxide layer may be grown on the substrate and nitride layer may be deposited by a suitable deposition process such as, e.g., a chemical vapor deposition (CVD) process, an atomic layer deposition (ALD), or the like. The resulting structure is depicted in FIG. 2B, with oxide layer 212 and nitride layer 214.

At operation 120 an amorphous silicon layer is deposited on the nitride layer 214. The amorphous silicon layer can be formed using any method. For example, the amorphous layer may be deposited by PVD or CVD depositions of silicon. At operation 122 a hard mask is applied. The resulting structure is depicted in FIG. 2C, with amorphous silicon layer 216 on nitride layer 214.

At operation 120 a hard mask layer 218 is formed on amorphous silicon layer 216. The masking layer 218 defines a pattern, which in turn defines the channels between fins on the silicon layer 210. The masking layer can be any well-known material suitable for defining a pattern in silicon layer 210. In some embodiments, masking layer 218 is a lithographically defined photo resist. In some embodiments, masking layer 218 is formed of a dielectric material that has been lithographically defined and then etched. In some embodiments, masking layer 218 can be a composite stack of materials, such as an oxide/nitride stack.

Once masking layer 218 has been defined, patterns are defined in amorphous silicon layer 216, e.g., by any known etching technique. For example, in some embodiments anisotropic plasma etch, or RIE, may be used to define patterns in amorphous silicon layer 216. The resulting structure is depicted in FIG. 2D. The layer of amorphous silicon 216 is patterned into discrete structures on the nitride surface 214.

At operation 135 the amorphous silicon layer 216 is oxidized. In some embodiments an oxide layer is grown on the amorphous silicon layer 216. Because the hardmask layer 218 remains on the top of the patterned amorphous silicon layer 216, the oxide grows only laterally on the amorphous silicon layer 216. The resulting structure is depicted in FIG. 2E. Referring to FIG. 2E, the amorphous silicon structures 216 each have oxide structures 222 formed on their respective sides.

At operation 140 the hard mask layer 218 is removed, e.g., by an etching process to expose the amorphous silicon layer 216 (FIG. 2F). At operation 145 the amorphous silicon layer 216 is removed, e.g., by an etching process such as a TMAH or NH4OH wet etch process. The resulting structure is depicted in FIG. 2G. At operation 150 the nitride layer 214, the oxide layer 216, and a portion of the silicon 210 are etched in one or more etching processes, resulting in the structure depicted in FIG. 2J. At operation 155 the oxide layer and the nitride layer 214 and the oxide layer 212 are removed, e.g., by a suitable etching process. This results in the structure depicted in FIG. 2K, i.e., a silicon substrate having a plurality of fins extending from the surface of the substrate. In subsequent processing, the trenches between the fins may be filled with metal-insulator-metal layers to form MIM capacitors and/or transistors.

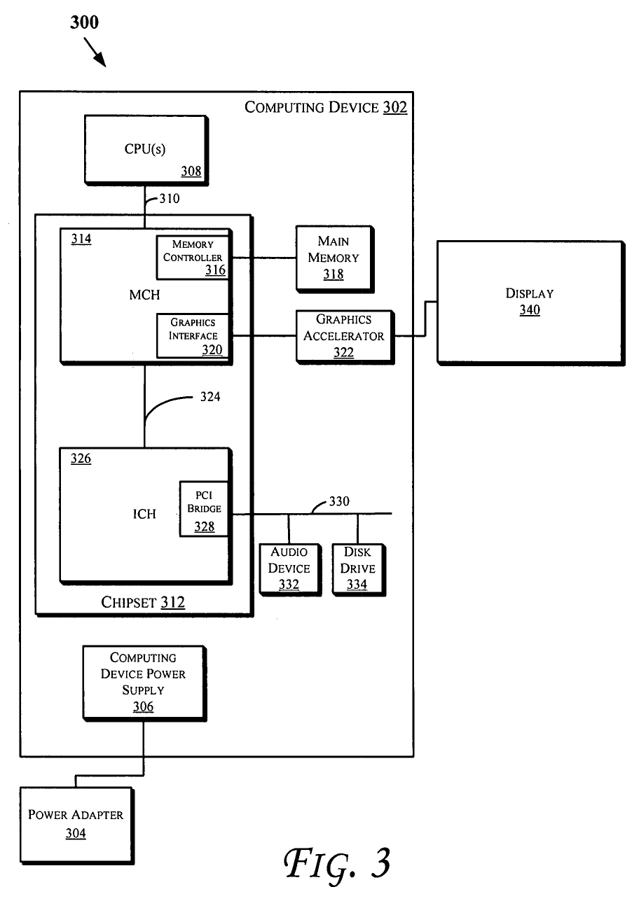

FIG. 3 is a schematic illustration of a computing system which may incorporate a thermal interface in accordance with some embodiments. The computer system 300 includes a computing device 302 and a power adapter 304 (e.g., to supply electrical power to the computing device 302). The computing device 302 may be any suitable computing device such as a laptop (or notebook) computer, a personal digital assistant, a desktop computing device (e.g., a workstation or a desktop computer), a rack-mounted computing device, and the like.

Electrical power may be provided to various components of the computing device 302 (e.g., through a computing device power supply 306) from one or more of the following sources: one or more battery packs, an alternating current (AC) outlet (e.g., through a transformer and/or adaptor such as a power adapter 304), automotive power supplies, airplane power supplies, and the like. In one embodiment, the power adapter 304 may transform the power supply source output (e.g., the AC outlet voltage of about 100 VAC to 240 VAC) to a direct current (DC) voltage ranging between about 7 VDC to 12.6 VDC. Accordingly, the power adapter 304 may be an AC/DC adapter.

The computing device 302 may also include one or more central processing unit(s) (CPUs) 308 coupled to a bus 310. In one embodiment, the CPU 308 may be one or more processors in the Pentium® family of processors including the Pentium® II processor family, Pentium® III processors, Pentium® IV processors available from Intel® Corporation of Santa Clara, Calif. Alternatively, other CPUs may be used, such as Intel's Itanium®, XEON™, and Celeron® processors. Also, one or more processors from other manufactures may be utilized. Moreover, the processors may have a single or multi core design.

A chipset 312 may be coupled to the bus 310. The chipset 312 may include a memory control hub (MCH) 314. The MCH 314 may include a memory controller 316 that is coupled to a main system memory 318. The main system memory 318 stores data and sequences of instructions that are executed by the CPU 308, or any other device included in the system 300. In one embodiment, the main system memory 318 includes random access memory (RAM); however, the main system memory 318 may be implemented using other memory types such as dynamic RAM (DRAM), synchronous DRAM (SDRAM), and the like. Additional devices may also be coupled to the bus 310, such as multiple CPUs and/or multiple system memories.

The MCH 314 may also include a graphics interface 320 coupled to a graphics accelerator 322. In one embodiment, the graphics interface 320 is coupled to the graphics accelerator 322 via an accelerated graphics port (AGP). In an embodiment, a display (such as a flat panel display) 340 may be coupled to the graphics interface 320 through, for example, a signal converter that translates a digital representation of an image stored in a storage device such as video memory or system memory into display signals that are interpreted and displayed by the display. The display 340 signals produced by the display device may pass through various control devices before being interpreted by and subsequently displayed on the display.

A hub interface 324 couples the MCH 314 to an input/output control hub (ICH) 326. The ICH 326 provides an interface to input/output (I/O) devices coupled to the computer system 300. The ICH 326 may be coupled to a peripheral component interconnect (PCI) bus. Hence, the ICH 326 includes a PCI bridge 328 that provides an interface to a PCI bus 330. The PCI bridge 328 provides a data path between the CPU 308 and peripheral devices. Additionally, other types of I/O interconnect topologies may be utilized such as the PCI Express™ architecture, available through Intel® Corporation of Santa Clara, Calif.

The PCI bus 330 may be coupled to an audio device 332 and one or more disk drive(s) 334. Other devices may be coupled to the PCI bus 330. In addition, the CPU 308 and the MCH 314 may be combined to form a single chip. Furthermore, the graphics accelerator 322 may be included within the MCH 314 in other embodiments.

Additionally, other peripherals coupled to the ICH 326 may include, in various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. Hence, the computing device 302 may include volatile and/or nonvolatile memory.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method, comprising:
forming a sacrificial amorphous silicon layer on a semiconductor substrate;
forming a hardmask on the amorphous silicon layer;
etching one or more lines in the sacrificial amorphous silicon layer;
growing oxide structures on the amorphous silicon layer; and
forming a trench in the semiconductor substrate between the oxide structures.

2. The method of claim 1, wherein forming a sacrificial amorphous silicon layer on a semiconductor substrate further comprises:
forming an oxide layer on the semiconductor substrate; and
forming a nitride layer on the oxide layer.

3. The method of claim 2, wherein forming a sacrificial amorphous silicon layer on a semiconductor substrate further comprises depositing amorphous silicon on the nitride layer.

4. The method of claim 1, wherein forming a hardmask on the amorphous silicon layer comprises forming a hardmask that defines at least one fin in the semiconductor substrate.

5. The method of claim 1, wherein growing oxide structures on the amorphous silicon layer comprises oxidizing the amorphous silicon layer.

6. The method of claim 1, wherein forming a trench in the semiconductor substrate between the oxide structures comprises:
etching the hardmask;
removing the amorphous silicon layer;
removing the nitride layer;
removing the oxide layer; and
etching the semiconductor substrate.

7. The method of claim 6, the semiconductor substrate is etched before the nitride layer and the oxide layer are removed.

8. The method of claim 1, further comprising implementing a lateral oxidation of the amorphous silicon.
